(19) United States
(12) Patent Application Publication
(10) Pub. No.: US 2007/0205439 A1
(43) Pub. Date: Sep. 6, 2007

(54) IMAGE PICKUP APPARATUS AND IMAGE PICKUP SYSTEM

(75) Inventors: Akira Okita, Yamato-shi (JP); Hiroki Hiyama, Zama-shi (JP); Ryuichi Mishima, Tokyo (JP); Asako Ura, Atsugi-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Ohta-ku (JP)

(21) Appl. No.: 11/680,742

(22) Filed: Mar. 1, 2007

(30) Foreign Application Priority Data
Mar. 6, 2006 (JP) 2006-059589

(51) Int. Cl. H01L 27/148

(52) U.S. Cl. 257/228

(57) ABSTRACT

An image pickup apparatus of the present invention includes a plurality of photoelectric conversion elements disposed on a semiconductor substrate, a multi-layer wiring structure including a plurality of interlayer insulation films disposed above the semiconductor substrate, and a passiation layer disposed above the multi-layer wiring structure. A first insulation layer is disposed below the under surface of the passiation layer; a second insulation layer is disposed above the top surface of the passiation layer; and the refractive indices of the passiation layer and the first insulation layer differ from each other, and the refractive indices of the passiation layer and the second insulation layer differ from each other. Moreover, planarization processing is performed to at least one layer of the interlayer insulation films and the first insulation layer. Furthermore, a first anti-reflection film is disposed between the passiation layer and the first insulation layer, and a second anti-reflection film is disposed between the passiation layer and the second insulation layer.

### BACKGROUND OF THE INVENTION

1. Field of the Invention

The present invention relates to an image pickup apparatus and an image pickup system, and more particularly to a digital camera, video camera, a copier and a facsimile.

2. Description of the Related Art

Many image pickup apparatus are mounted on digital cameras, video cameras, copiers, facsimiles. The image pickup apparatus severally have pixels arranged in one dimension or two dimensions, each of which pixels includes a photoelectric conversion element. CCD image sensors and CMOS image sensors are used as the image pickup apparatus. CMOS image sensors are amplification type image pickup apparatus. Recently, an image pickup apparatus having many pixels and formed in a small chip has been required, and the introduction of semiconductor techniques such as a fine wiring rule of a dynamic random access memory (DRAM) as a representative example has been promoted. The introduced semiconductor techniques are, for example, as follows. In a CMOS image sensor, at least two wiring layers are used. Planarization techniques, a representative example of which is chemical mechanical polishing (CMP), are used so as to arrange the plural wiring layers to be fine. For example, Japanese Patent Application Laid-Open No. 2001-284566 discusses an example of using the CMP method as the planarization processing of the interlayer insulation film of a CMOS image sensor. The patent publication then discusses a configuration in which a light shielding film is formed on the interlayer insulation film, the surface of which has been planarized, and a passivation film is disposed to cover the light shielding film.

Moreover, not only the semiconductor techniques for such miniaturization, but also optical techniques are deeply related to the image pickup apparatus, and various considerations are required.

For example, Japanese Patent Application Laid-Open No. H11-103037 discusses a technique of providing an interlayer lens above a light receiving sensor unit. The patent publication further discusses the configuration of arranging anti-reflection films over and under the interlayer lens, so that the sensitivity of the CCD image sensor is improved.

If a silicon nitride film (SiN film) having a high refractive index is formed on the interlayer insulation film, the surface of which has been planarized by the CMP method or the like in the CMOS image sensor including the plural wiring layers discussed in Japanese Patent Application Laid-Open No. 2001-284566, the following problem may arise.

The problem is the occurrence of color unevenness of a photographed image in which some places are colored to be green or red when a uniform white luminance surface is photographed. The present inventor found that the phenomenon was principally caused by the interference of an incident light into a light receiving unit of a photoelectric conversion element with the light reflected on the interface between the light receiving unit and the insulation film on the light receiving unit, and the reflected light being reflected again on the interface between the SiN film and the interlayer insulation film. Then, the inventor found that the interference depended on the film thickness of the interlayer insulation film.

Accordingly, it is an object of the present invention to provide an image pickup apparatus in which the color unevenness is reduced.

### SUMMARY OF THE INVENTION

An color image pickup apparatus comprises: a plurality of photoelectric conversion elements disposed on a semiconductor substrate; a multi-layer wiring structure including a plurality of interlayer insulation films disposed over the semiconductor substrate; a passiation layer disposed over the multi-layer wiring structure; a first insulation layer disposed below an under surface of the passiation layer; and a second insulation layer disposed above a top surface of the passiation layer, wherein refractive indices of the passiation layer and the first insulation layer are different from each other, and refractive indices of the passiation layer and the second insulation layer are different from each other; planarization processing is performed to at least one layer of the plurality of interlayer insulation films and the first insulation layer; a first anti-reflection film is disposed between the passiation layer and the first insulation layer, the first anti-reflection film contacting with the passiation layer and the first insulation layer; and a second anti-reflection film is disposed between the passiation layer and the second insulation layer, the second anti-reflection film contacting with the passiation layer and the first insulation layer.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a schematic sectional view illustrating an image pickup apparatus according to a first exemplary embodiment.

FIG. 2 is a schematic sectional view illustrating the image pickup apparatus of the first exemplary embodiment.

FIG. 3 is a schematic sectional view illustrating an image pickup apparatus of a second exemplary embodiment.

FIG. 4 is a configuration diagram illustrating an example of an image pickup system.

FIG. 5 is a configuration diagram illustrating an example of an image pickup system.

FIG. 6 is a diagram illustrating an example of a pixel circuit.

FIG. 7 is a schematic view of a conventional image pickup apparatus.

FIG. 8 is a graph illustrating the total film thicknesses of interlayer insulation films and acquired R/G ratios of the conventional image pickup apparatus.

FIG. 9 is a graph illustrating the total film thicknesses of interlayer insulation films and acquired R/G ratios of the image pickup apparatus according to the first exemplary embodiment.

The accompanying drawings, which are incorporated in and constitute a part of the specification, illustrate embodiments of the invention and, together with the description, serve to explain the principles of the invention.

### DESCRIPTION OF THE EMBODIMENTS

Before describing the exemplary embodiments of the present invention, the color unevenness is described which arises when a silicon nitride (SiN) film having a high refractive index is disposed on an interlayer insulation film, the surface of which has been planarized by the CMP method or the like.

The color unevenness arises by the interference of an incident light into a light receiving unit, as mentioned above. Consequently, if the interlayer insulation film is not planarized, namely if no macroscopic film thickness unevenness owing to planarization arise in a pixel portion, as the case of Japanese Patent Application Laid-Open No. H11-103037, the color unevenness does not arise. The reason why the color unevenness does not arise is that the configuration discussed in Japanese Patent Application Laid-Open No. H11-103037 includes an interlayer lens disposed in a concave portion of the interlayer insulation film so as to have film thickness unevenness in one pixel of the interlayer insulation film.

The color unevenness becomes remarkable when a film having a different refractive index is disposed on the planarized interlayer insulation film. That is, the color unevenness becomes remarkable when the distance between the light receiving unit and the film having the different refractive index, which film is disposed on the interlayer insulation film, becomes uneven in an image pickup area in an image pickup apparatus including the film having the different refractive index.

First, the interference of an incident light is described. FIG. 7 illustrates a schematic sectional view of the CMOS image sensor discussed in Japanese Patent Application Laid-Open No. 2001-284566. The CMOS image sensor comprises a silicon semiconductor substrate (hereinafter referred to as a substrate) 701, a photodiode 702, which is a light receiving unit, an interlayer insulation film 703, a light shielding film 704, a planarization film 706 and wiring layers 708 and 709. A P—SiN film (silicon nitride film formed by the plasma CVD method) 705 is deposited on the light shielding film 704 as a passivation layer. Furthermore, a micro lens 707 is disposed.

Hereupon, the refractive index of each layer is described as follows: the refractive index of passivation layer 705 is 2.0, and the refractive index of the planarization film 706 is within a range of from 1.5 to 1.6. Furthermore, generally, the refractive index of a silicon semiconductor substrate is within a range of from 3.50 to 5.20, and the refractive index of an interlayer insulation film using SiO is within a range of from 1.40 to 1.50.

In such a case, because the differences of the refractive indices at the interface between the substrate 701 and the interlayer insulation film 703, the interface between the interlayer insulation film 703 and the passivation layer 705, and the interface between the passivation layer 705 and the planarization film 706 are large, the reflection of a light at each interface arises easily. In FIG. 7, the reflected lights at the surface of the light receiving unit and at the passiation layer are denoted by ref1 and ref2, respectively. Although the reflected light ref2 is shown as only one light for simplification, the reflected lights ref2 actually has the reflected lights at the interface between the passivation layer 705 and interlayer insulation layer 703, and at the interface between the passivation layer 705 and the planarization film 706. These reflected lights interfere with each other. Therefore, the incident light quantity into the light receiving unit 702 has wavelength dependency.

If planarization is performed to at least one interlayer insulation film in such a configuration, the interlayer insulation film is flat in a microscopic range (from several μm to several tens μm). However, the film thickness becomes uneven in a macroscopic range (several mm or more) (the unevenness of the film thickness). For example, the film thickness of the interlayer insulation film that has been polished by the CMP method is influenced by the arrangement density of elements such as MOS transistors and wiring. Here, an image pickup apparatus comprises a peripheral circuit portion and a pixel portion (also referred to as an image pickup area) where pixels are arranged. Because the arrangement density of the peripheral circuit portion is higher than that of the pixel portion, the polishing rate of the CMP method in the peripheral circuit portion differs from that in the pixel portion. Consequently, the film thickness of the interlayer insulation film of the image pickup apparatus is thick in the peripheral circuit portion and is thin in the pixel portion. Because the film thickness gradually changes at the boundary of the peripheral circuit portion and the pixel portion consequently, the unevenness of the film thickness is caused in the pixel portion. Moreover, even if the wiring densities do not differ so much, the unevenness of film thickness of the interlayer insulation film sometimes arises in the pixel portion. Furthermore, even if the etch back method, which is another planarization technique, is used, the dependency in a surface in the image pickup apparatus is large. Consequently, the unevenness of film thickness occurs in the interlayer insulation film in the image pickup apparatus.

Then, if at least one layer is planarized, the unevenness of film thickness is followed by the interlayer insulation films that will be formed after the planarized film.

If the unevenness of film thickness has occurred in the image pickup area in view of a wide range in this way, then the degree of the aforesaid interference differs dependently on the place in the image pickup area. Consequently, the color unevenness of the image pickup apparatus arises as a result. That is, it can be said that the problem of the color unevenness is remarkable when a film having a refractive index different from those of the interlayer insulation films is used as a passiation layer in the case where the unevenness of the total film thickness of the interlayer insulation films has arisen in an image pickup area in view of a wide range.

On the other hand, Japanese Patent Application Laid-Open No. 2001-284566 does not find the technical problem of color unevenness arising in the case of using a passiation layer having a refractive index different from those of the circumjacent films, the color unevenness caused by the interference of an incident light with a re-reflected light that has reflected on the surface of the light receiving unit and has again reflected on the interface of the passiation layer. Japanese Patent Application Laid-Open No. 2001-284566 discusses the problem of the refraction of an incident light into an unexpected direction caused by a step of the SiN film disposed over the wiring as the passiation layer, and discusses the planarization of the SiN film to the problem. However, the reflected light from the light receiving unit is reflected at the interface between the passiation layer having the high refractive index and the interlayer insulation film, and the re-reflected light again enters the light receiving unit. At that time, an incident light into the light receiving unit interferes with the re-reflected light, and the degree of the interference changes owing to the unevenness of the film thickness of the interlayer insulation film. Japanese Patent Application Laid-Open No. 2001-284566 does not recognize such a problem. The configuration of Japanese Patent Application Laid-Open No. 2001-284566 causes the aforesaid color unevenness, and then the image quality degrades.

Accordingly, the present invention enables an image pickup apparatus including a passiation layer and having received planarization processing to reduce the re-reflection of a light reflected on a light receiving unit on an interface between the passiation layer and an insulation layer. Consequently, because it becomes possible to reduce the mutual strengthening of a light entering the light receiving unit which strengthening is caused by the re-reflected light, color unevenness can be reduced.

The color image pickup apparatus of the present invention includes a plurality of photoelectric conversion elements arranged on a semiconductor substrate, a multi-layer wiring structure including a plurality of interlayer insulation films disposed on the semiconductor substrate, and a passiation layer disposed on the multi-layer wiring structure.

Then, a first insulation layer is disposed on the under surface of the passiation layer, and a second insulation layer is disposed on the top surface of the passiation layer. The refractive index of the passiation layer differs from that of the first insulation layer, and the refractive index of the passiation layer also differs from that of the second insulation layer. Furthermore, the planarization processing is performed to at least one layer of the interlayer insulation films and the first insulation layer. Then, a first anti-reflection film is disposed between the passiation layer and the first insulation layer, and a second anti-reflection film is disposed between the passiation layer and the second insulation layer.

The configuration enables the reduction of the reflection at the upper and the lower interfaces of the passiation layer of the light reflected on the light receiving unit. Then, the interference of the reflected light decreases, and the color unevenness reduces.

Moreover, not only the improvement of transmittance owing to a refractive index condition at each anti-reflection film, but also the formation of the film thickness of each anti-reflection film to the one by which the reflected lights at the upper and the lower interfaces of the anti-reflection film weaken each other enable the more reduction of the light quantities of the reflective lights. As a result, the light quantity of the reflection light ref2 illustrated in FIG. 7 schematically is reduced.

Now the color unevenness is described. When a general semiconductor device is planarized by the CMP method, the unevenness of film thickness owing to the CMP method in view of wide range seldom influences the characteristics of the device. However, as mentioned above, color unevenness occurs owing to the unevenness of film thickness in an image pickup area in view of wide range in the image pickup apparatus.

Furthermore, the relation between the film thickness of the interlayer insulation film and the color unevenness is described using FIG. 7. If the total film thickness of interlayer insulation film from the surface of the light receiving unit to the uppermost part of the interlayer insulation layer as shown in FIG. 7 is denoted by L, the refractive index is dented by n, and the wavelength is denoted by λ, then the relations of these quantities in reflection become as follows.

The lights that satisfy the following Expression 1 strengthen each other:
2nL=(λ/2)×(2m) (Expression 1),
and the lights that satisfy the following Expression 2 weaken each other:
2nL=(λ/2)×(2m+1) (Expression 2)

where m denotes an integer. An example of the relations between the reflected lights and the total film thicknesses L of interlayer insulation films is shown. When the refractive index n of an interlayer insulation film is 1.46 and the total film thickness L is 3000 nm, the wavelength λ of 548 nm (m=16) strengthen each other. On the other hand, when the total film thickness L changed to 3100 nm, the relation changed to strengthen the wavelength λ of 566 nm (m=16).

The strengthening wavelengths in visible light (400-700 nm) are collected in Table 1. It is known from Table 1 that the strengthening wavelengths change dependently on the total film thickness L of the interlayer insulation film.

TABLE 1

| m | L = 3000 nm | L = 3100 nm | CF |
|---|---|---|---|
| 13 | 674 | 696 | R |
| 14 | 626 | 647 | R |
| 15 | 584 | 603 | R-G |
| 16 | 548 | 566 | G |
| 17 | 515 | 532 | G |
| 18 | 487 | 503 | G-B |
| 19 | 461 | 476 | B |
| 20 | 438 | 453 | B |
| 21 | 417 | 431 | B |

Hereupon, the configuration using a color filter (CF) including three primary colors of R, G and B is described. Pixels are arranged correspondingly to the B (wavelength: 400-500 nm), the G (wavelength: 500-600 nm) and the R (wavelength: 600-700 nm) of the CF, respectively. If the case in which the same light enters a plurality of pixels of the same color of the CF is examined, the differences of the total film thicknesses of the interlayer insulation films corresponding to the pixels from one another clarify the wavelengths strengthened by each other among the wavelength band corresponding to each color.

Moreover, for example, if the wavelength band of 550-650 nm, which is the boundary between R and G, is noted, the output of the pixel of G of the CF becomes large at the film thickness L of 3000 nm, and the output of the pixel of R of the CF becomes large at the film thickness L of 3100 nm.

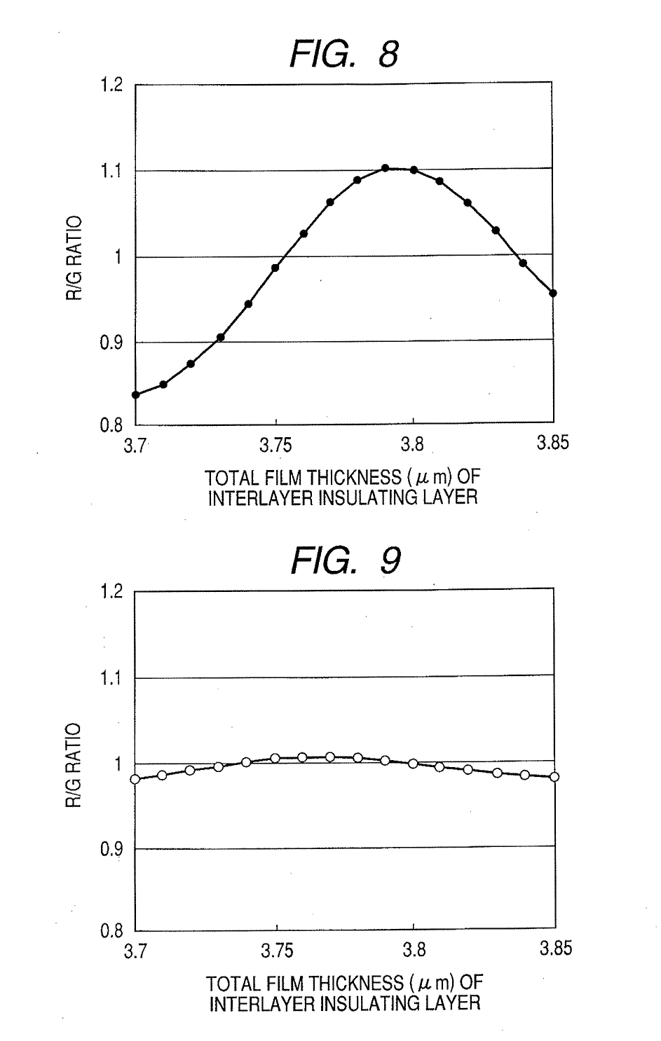

Consequently, the output ratio of R, G and B changes dependently on the total film thickness of the interlayer insulation film. The change is illustrated in FIG. 8. The data of FIG. 8 was acquired by the simulation of output ratios R to G (R/G ratios) of the signals output from the image pickup apparatus comprising the CF to the total film thicknesses of the interlayer insulation film of an image pickup apparatus comprising a passiation layer having an anti-reflection film having the refractive index of 1.60, which anti-reflection film is formed on the under surface of the passiation layer. The R/G ratios change between the case where the output of R is larger and the case where the output of G is larger according to the changes of the film thickness.

Consequently, when a uniform white light enters an image pickup apparatus comprising a pixel portion having unevenness of the total film thickness L of an interlayer insulation film, color unevenness arises in the image pickup apparatus. Furthermore, because only specific wavelengths have strong peaks under the environment of a light source having bright lines, the tendency of such color unevenness becomes remarkable. The light source having the bright lines is, for example, a three band fluorescent lamp, which has become the mainstream of household lighting. Because the three band fluorescent lamp has bright lines of three wavelengths of blue, green and red, to which colors human eyes have high sensitivity, the three band fluorescent lamp is the lighting having high color rendering properties. If the image pickup apparatus according to the present invention is used under such an environment, the image pickup apparatus are especially effective.

Next, the absolute value of the total film thickness L of an interlayer insulation film and the influences of the color unevenness are described. The cases of the total film thicknesses L are 3,500 nm and 1,000 nm are compared with each other. If the refractive index n of the interlayer insulation film is set to be 1.46, in the range of the visible light, the strengthening wavelengths in the case where the total film thickness L is 3,500 nm are eleven wavelengths having the k that is within the range of 15≦k≦25. That is, when the wavelengths and the intensities of the light are plotted, eleven peaks appear. However, the strengthening wavelengths in the case where the total film thickness L is 1,000 nm are three wavelengths having the k within the range of 5≦k≦7. Consequently, the intervals of the strengthening wavelengths in the case where the total film thickness L is 1,000 nm is wider than that in the case where the total film thickness L is 3,500 nm. Accordingly, if the insulation layer is made to be thinner from 3,500 nm to 1,000 nm, the spectral characteristic is smoothed. Consequently, it is known that the color unevenness is reduced to be about one third.

Consequently, if the total film thickness of the interlayer insulation film is thick to be from 3 μm to 5 μm and the macroscopic unevenness of the film thickness by the planarization processing represented by the CMP method has occurred, color unevenness easily arises, and the present invention is especially effective. That is, the color unevenness easily arises in a CMOS image sensor having a multi-layer wiring structure.

The passiation layer is preferably formed of a p-SiN film, which is generally highly effective to terminating the dangling bond of the silicon substrate owing to the hydrogen sintering effect in addition to the function of the passiation layer. Incidentally, the interlayer insulation film is a film insulating and separating the wiring layers in a multi-layer wiring structure. Moreover, the anti-reflection film means a film decreasing the quantity of reflected light.

Although the semiconductor substrate, which is the substrate of materials, is expressed as a “substrate”, the semiconductor substrate may include the processed substrate of materials as follows. For example, a member in the state in which one or more semiconductor regions or the like are formed, a member on the way of a series of manufacturing processes, and a member having received a series of manufacturing processes can be called as the substrate. Furthermore, the expression of “on the semiconductor substrate” means “on the main surface of the semiconductor substrate, on which the photoelectric conversion elements are formed.” Moreover, the expressions of “laminating direction” and “upper direction” indicate the direction from the main surface of the semiconductor substrate toward the incident light. The expression of “lower direction” indicates the reverse direction of the “upper direction,” or indicates the direction from the main surface of the semiconductor substrate to the inside of the semiconductor substrate.

In the following, the exemplary embodiments of the present invention are described, referring to the attached drawings.

(Circuit Configuration of Pixel)

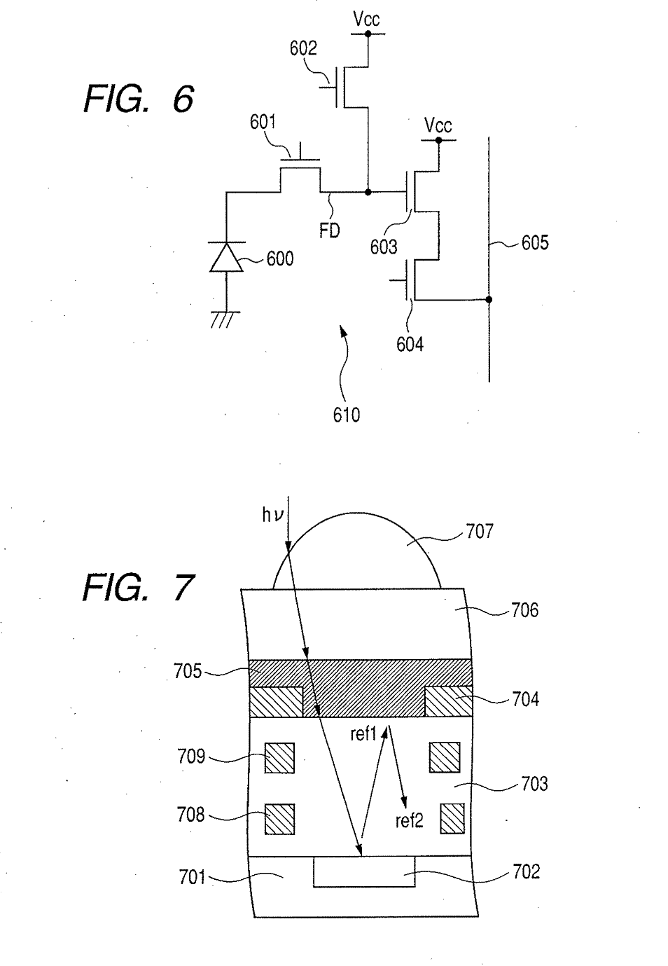

First, the pixels of the image pickup apparatus are described. FIG. 6 illustrates an example of the circuit configuration of a pixel in a CMOS type image sensor, a kind of the image pickup apparatus. The pixel is denoted by a reference numeral 610.

The pixel 610 includes a photodiode 600, which is a photoelectric conversion element, a transfer transistor 601, a reset transistor 602, an amplification transistor 603 and a selection transistor 604. Here, an electric power cable is denoted by a reference mark Vcc, and an output line is denoted by a reference numeral 605.

The anode of the photodiode 600 is grounded, and the cathode of the photodiode 600 is connected to the source of the transfer transistor 601. Moreover, the source of the transfer transistor 601 can be commonly used as the cathode of the photodiode 600.

The drain of the transfer transistor 601 comprises a floating diffusion (hereinafter referred to as FD), which is a transfer region, and the gate of the transfer transistor 601 is connected to a transfer signal line. Furthermore, the drain of the reset transistor 602 is connected to the electric power cable Vcc, and the source of the reset transistor 602 comprises the FD. The gate of the reset transistor 602 is connected to a reset signal line.

The drain of the amplification transistor 603 is connected to the electric power cable Vcc, and the source of the amplification transistor 603 is connected to the drain of the selection transistor 604. The gate of the amplification transistor 603 is connected to the FD. The drain of the selection transistor 604 is connected to the source of the amplification transistor 603, and the source of the selection transistor 604 is connected to the output line 605. The gate of the selection transistor 604 is connected to a vertical selection line driven by a vertical selection circuit (not shown).

The circuit configuration mentioned above can be applied to all of the embodiments of the present invention. However, other circuit configurations such as the one not including the transfer transistor and the one in which a plurality of pixels shares the transistors can be also applied to the present invention. Moreover, as the photoelectric conversion element, not only the photodiode, but also a phototransistor and the like can be used.

### First Exemplary Embodiment

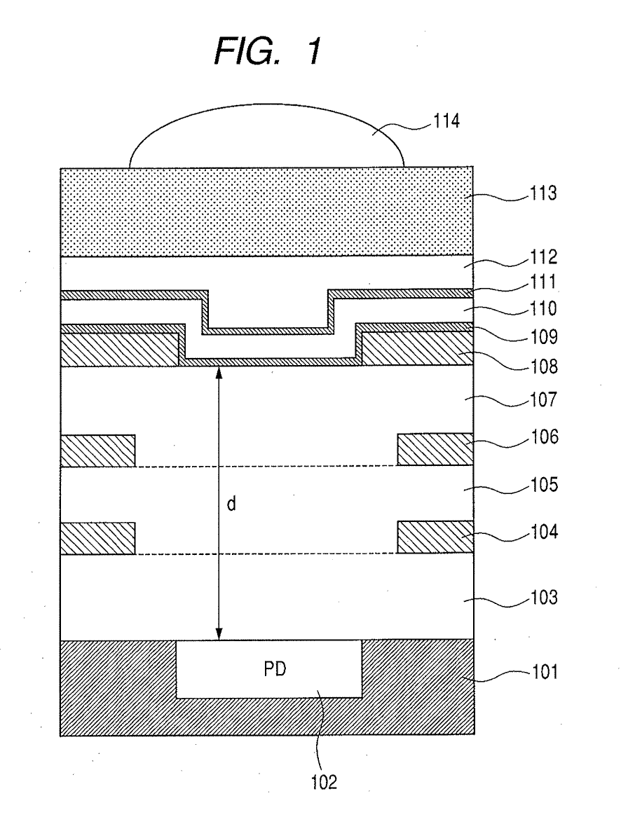

FIG. 1 illustrates a first exemplary embodiment. FIG. 1 is a schematic sectional view illustrating a photodiode in the pixel of the image pickup apparatus illustrated in FIG. 6. In FIG. 1, the photodiode (sometimes referred to as a light receiving unit) includes a p-type semiconductor region 101 and an n-type semiconductor region 102. Another p-type semiconductor region is sometimes further formed on the upper side of the n-type semiconductor region 102. A first interlayer insulation film 103 is formed of, for example, a SiO film formed by the plasma CVD method. A first wiring layer 104 is formed of, for example, aluminum after the planarization of the interlayer insulation film 103 by, for example, the CMP method. A second interlayer insulation film 105, a second wiring layer 106, a third interlayer insulation film 107 and a third wiring layer 108 can be formed of the same material and by the same process as those of the first layer interlayer insulation film and the first wiring layer, respectively. As another method and another material, the planarization by the etch back method and a wiring layer made of cupper can be cited.

As illustrated in the drawing, the sum of each film thickness of the plural interlayer insulation films is supposed as a film thickness d. Because each interlayer insulation film is planarized by the CMP method, the film thickness d is constant in a narrow region, for example, in one pixel. However, unevenness arises in a macroscopic film thickness when the image pickup area is wholly observed.

Moreover, passiation layer and anti-reflection films are disposed over the third interlayer insulation film 107, which is the interlayer insulation film at the uppermost part in the laminating direction. First, a first anti-reflection film 109 is formed of a P—SiON film. A passiation layer 110 is disposed on the first anti-reflection film 109. The passiation layer 110 is a P—SiN film. A second anti-reflection film 111 is formed of a P—SiON film. A resin layer 112 functions as a planarization layer, and an insulation layer such as a BPSG film can be also used in addition to the resin layer 112. Furthermore, a color filer 113 and a micro lens 114 are disposed over the resin layer 112. The third interlayer insulation film 107 and the resin layer 112 are also referred to as the first insulation layer and the second insulation layer, respectively. At least the passiation layer and the films near the layer are required to severally have a refractive index different from each other. As the passiation layer, a silicon nitride film is suitably used because the film has a high protection function and the sintering effect of hydrogen. However, the passivation layer has a minute crystal structure. So the passivation layer has a refractive index higher than those of the silicon oxide film used as the interlayer insulation films, the color filter, and the organic film as the planarization film. Consequently, the refractive index of the passiation layer and those of the films near the passiation layer are frequently different from each other.

The mechanism of the occurrence of color unevenness is that a reflection light from the surface of the light receiving unit 102 is reflected on the passiation layer to enter the light receiving unit 102 again, which is the primary factor of the occurrence of the color unevenness. For reducing the color unevenness, it is just needed to reduce the re-reflection of the light reflected from the light receiving unit 102 on the passiation layer. Accordingly, the first anti-reflection film 109 and the second anti-reflection film 111 are formed on the upper and the lower surfaces of the P—SiN film 110 to reduce the re-reflection in the present exemplary embodiment.

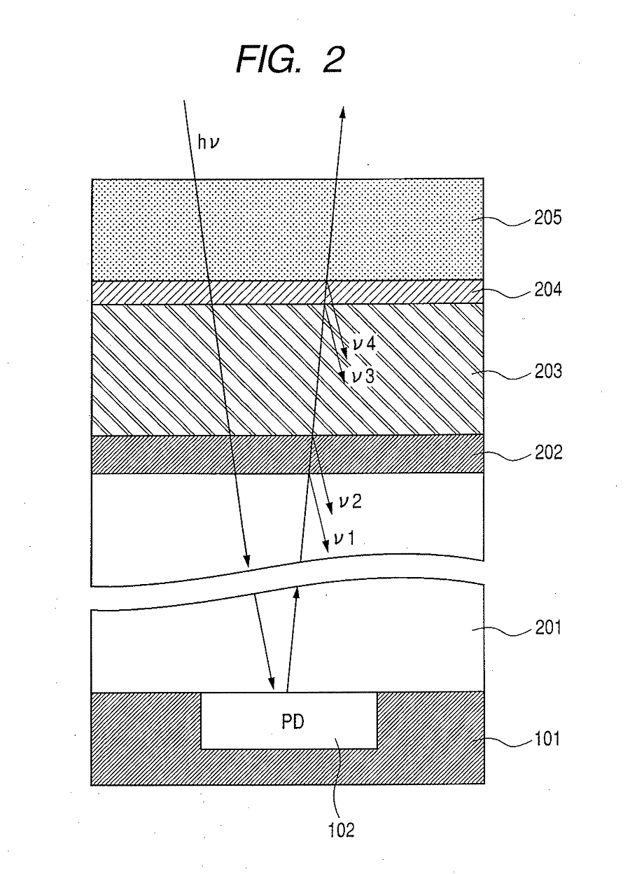

The anti-reflection films are described in detail, referring to FIG. 2. In FIG. 2, a first insulation layer 201 includes a plurality of interlayer insulation films to be wholly expressed as an insulation film of a single layer having a refractive index n for simplification. A first anti-reflection film 202 has a refractive index n2 and a thickness d2; a passiation layer 203 has a refractive index n3 and a thickness d3; a second anti-reflection film 204 has a refractive index n4 and a thickness d4; and a second insulation layer 205 is a resin layer having a refractive index n5. In addition, the components having the same functions as those illustrated in FIG. 1 are denoted by the same marks as those in FIG. 1. In the present exemplary embodiment, the passiation layer is formed of a P—SiN film; the first insulation layer disposed below the passiation layer is formed of a P—SiO film; and the second insulation layer disposed above the passiation layer is formed of a resin layer. The refractive index of each film is, for example, as follows: n1=1.46, n3=2.00, n5=1.55. Moreover, an incident light hν and the reflected light thereof are severally denoted by an arrow in FIG. 2. The reflected light at each interface is denoted by reference marks ν1-ν4.

In this case, the features of the first anti-reflection film 202 and the second anti-reflection film 204 that are to be inserted into the first interface between the first insulation layer 201 and the passiation layer 203 and the second interface between the passiation layer 203 and the second insulation layer 205, respectively, can be determined as follows.

First, the following relational expressions are given to the first anti-reflection film 202.

(Cases of n3>n1>n2 and n2>n3>n1)
2n2d2=(λ/2)×2m(m=1, 2, . . . ) (Expression 3)

(Case of n3>n2>n1)
2n2d2=(λ/2)×(2m+1)(m=0, 1, 2, . . . ) (Expression 4)

When the relations are satisfied, the reflected lights ν1 and ν2 interfere with each other to weaken each other to the minimum degree, and consequently the reflected lights toward the light receiving unit 102 are reduced.

The following relational expressions are similarly given to the second anti-reflection film 204.

(Cases of n3>n5>n4 and n4>n3>n5)
2n4d4=(λ/2)×2m(m=1, 2, . . . ) (Expression 5)

(Case of n3>n4>n5)
2n4d4=(λ/2)×(2m+1)(m=0, 1, 2, . . . ) (Expression 6)

When the relations are satisfied, the reflected lights ν3 and ν4 interfere with each other to weaken each other to the minimum degree, and the reflected lights toward the light receiving unit 102 are reduced. Incidentally, although the refractive indices and the film thicknesses that satisfy the expressions are preferable because the reflected lights can be weakened to the minimum degrees, it is not always necessary to satisfy the expressions completely. The values may be within a predetermined range. The details of the predetermined range will be described later.

The provision of the first anti-reflection film 202 and the second anti-reflection film 204 that satisfy the above-mentioned expressions enables the decrease of the reflection at the interfaces of the passiation layer 203.

Consequently, even if the sum d of the film thicknesses of the interlayer insulation films in FIG. 1 is dispersed owing to the planarization by the CMP method, color unevenness can be reduced because the reflected lights are weakened at the interfaces of the passiation layer. Moreover, in the environment under a light source having bright lines, color unevenness is especially easily seen, and consequently the anti-reflection films are especially effective in such an environment.

Now, the unevenness of the film thicknesses of the anti-reflection films is described. First, it has been already described as for the unevenness of the film thicknesses of the interlayer insulation films that the total film thickness of the interlayer insulation films becomes large in an image pickup apparatus including two wiring layers or more as the present exemplary embodiment and the unevenness of the film thickness also becomes large. The magnitude of the unevenness of the film thickness is sometimes larger than the wavelength of the light used in the image pickup apparatus. For example, if the total film thickness d of interlayer insulation films is designed to be 3,000 nm and the unevenness of the film thickness on manufacturing is supposed to be 10%, then the unevenness quantity becomes 300 nm. Because the refractive indices of the interlayer insulation films of the present exemplary embodiment are 1.46, the optical distance becomes 300×1.46=438 nm. The value corresponds to the wavelength range (400-700 nm) of the visible light used by the image pickup apparatus, and the optical length is the one that is easily influenced by the interference.

On the other hand, the film thicknesses of the first anti-reflection film 202 and the second anti-reflection film 204, which are illustrated in FIG. 2, are as follows. It is supposed that m=1 and a wavelength is within a range of 400-700 nm in the relational expressions of (Expression 3) to (Expression 6). Moreover, if the refractive indices of the first and second anti-reflection films are supposed to 1.7 on the supposition that P—SiON is used as the films, the film thicknesses of the films become about 100-300 nm. Even if the unevenness of the film thicknesses on manufacturing is supposed to be 10%, the unevenness becomes 10-30 nm. Consequently, the unevenness of the optical distance is sufficiently small in comparison with the range of the wavelength range (400-700 nm) of the visible light. Therefore, even if the first anti-reflection film 202 and the second anti-reflection film 204 are provided, these anti-reflection films 202 and 204 are hard to influence the characteristics of the image pickup apparatus. In consequence, if the first anti-reflection film 202 and the second anti-reflection film 204 are formed above and below the passiation layer 203, the color unevenness caused by the unevenness of the insulation films can be reduced without causing the color unevenness owing to the unevenness of the film thicknesses of the anti-reflection films 202 and 204.

Moreover, to put it concretely, it is when the film thicknesses of the interlayer insulation films severally have the unevenness equal to the one quarter of the wavelength of an incident light or more as shown in (Expression 3) to (Expression 6) that the influence of the interference is exerted owing to the unevenness. That is, if the refractive index of an interlayer insulation film is denoted by n, the unevenness of the film thickness thereof is denoted by Δ, and the wavelength of an incident light is dented by λ, the condition is: n×Δ>λ/4. Because n is 1.46 or more in the present exemplary embodiment, the color unevenness is easy to be produced when the unevenness Δ is roughly larger than λ/6. For example, if the wavelength λ is 600 nm, then the unevenness becomes 100 nm or more. If the first and the second anti-reflection films are formed when the interlayer insulation film having such unevenness of the film thickness is provided, the reflection can be especially reduced.

The concrete film thicknesses and the refractive indices of the anti-reflection films of the present exemplary embodiment are described, referring to FIG. 2. For example, if the color unevenness caused by a light source having a bright line at the wavelength λ of 600 nm is reduced in the case where the refraction index n3 of the passiation layer is 2.00 and the refraction index n1 of the insulation layer is 1.46, then the film thicknesses and the refractive indices of the anti-reflection films become as follows. First, as for the refractive index and the film thickness of the first anti-reflection film, when 2n2d2=λ/2 is used from (Expression 4), a condition:
2d2=150 nm (Expression 7)
is introduced. At this time, if the magnitudes of the reflected lights ν1 and ν2 are made to be uniformed, the more reduction of the reflected light is expected. In consequence, the refractive index satisfying the following relation that is introduced from the expression of reflection is preferable.
n2=√n1√n3=1.71 (Expression 8)

As a result, the film thickness d2 becomes 88 nm. Hereupon, the passiation layer 203 has a thickness of 300-400 nm or more.

Incidentally, because the reflected lights ν1 and ν2 weakens each other owing to the difference of phases to take effect in present exemplary embodiment, the relational expression between 2n2d2 and the wavelength λ is adequate as long as the relation expression satisfies the following range.
λ/2−λ/4≦2n2d2≦λ/2+λ/4 (Expression 9)

Moreover, also the refractive index and the film thickness of the second anti-reflection film 204 can be similarly obtained. Moreover, the relational expression may be similarly adequate as long as it satisfies the following range.
λ/2−λ/4≦2n4d4≦λ/2+λ/4 (Expression 10)

Although the film thickness is obtained from (Expression 4) in the present exemplary embodiment, the film thickness may be obtained suitably using (Expression 3) correspondingly to the relations of the refractive indices of the passiation layer and the insulation layer. Also in that case, relational expressions similar to (Expression 9) and (Expression 10) can be used.

Now, to be concretely, the film thicknesses of the anti-reflection films corresponding to a three band fluorescent lamp, which is generally spread, is tried to be obtained. First, the three band fluorescent lamp has a bright line in each of the wavelength ranges corresponding to R, G and B, the three primary colors. The bright line of R is about 610 nm; the bright line of G is about 540 nm; and the bright line of B is about 450 nm. However, in the spectral characteristics of the three band fluorescent lamp, the spectral characteristic corresponding to B is rather wide in comparison with those of the other twos, and also the strength of the spectral characteristic corresponding to B is lower than those of the other twos. Moreover, because the quantum efficiency corresponding to B is also lower in comparison with those of the other twos, the sensitivity of the image pickup apparatus is also hard to rise. Accordingly, it is preferable to design the anti-reflection films, noticing G and R, which are easy to exert influences owing to color unevenness.

First, the film thickness of the first anti-reflection film is obtained. It is supposed that the refractive index n3 of the passiation layer is 2.00, the refractive index n1 of the insulation layer is 1.46, and the wavelength of the bright line of G is 544 nm and the wavelength of the bright line of R is 612 nm. Moreover, the refractive index n2 of the anti-reflection film is supposed to be 1.71 obtained by (Expression 8).

2n2d2=λ/2, and dG=79.5 nm in order to reduce the reflection quantity of the light having the bright line of G, and further dR=89.5 nm in order to reduce the reflection quantity of the light having the bright line of R. Accordingly, the film thickness is just needed to be d=(dR+dG)/2=84.4 nm in order to reduce the reflection quantities of the lights of both the bright lines. That is, in order to reduce the reflection quantities of the lights of both the bright lines, it is appropriate to obtain the film thickness from the average value of the wavelengths of the bright lines of G and R.

Furthermore, the following relational expressions are given from (Expression 9).
544/4≦2n2d2≦(3×544)/4 (Expression 11)
612/4≦2n2d2≦(3×612)/4 (Expression 12)

The range of the film thickness corresponding to G is about 39.8≦d2≦about 119, and the range of the film thickness corresponding to R is about 44.7≦d2≦about 134. In consequence, if the anti-reflection film has the film thickness in the range of about 44.7-119 nm, the anti-reflection film is effective to any of the bright lines. Moreover, even if more bright lines exist, a film thickness for reducing the reflection of the plurality of bright lines can be obtained by the similar method. Also as for the second anti-reflection film, the film thickness thereof can be similarly obtained, namely the refractive index and the film thickness are just needed to satisfy (Expression 10).

The refractive indices n2 and n4 and the film thicknesses d2 and d4 of the anti-reflection films should be determined in the way mentioned above. But, when the refractive index n1 of the insulation film 201 and the refractive index n5 of the resin layer 205 are different from the refractive indices n2 and n4, respectively, the optimum values of the indices n2 and n4 and the optimum values of the thicknesses d2 and d4 are different values from the aforesaid values, respectively.

However, the manufacturing cost can be cut down by using the materials having the same refractive index (refractive index n6) as the first anti-reflection film 202 and the second anti-reflection film 204 to unify their film types. At that time, the same refractive index n6 further needs to satisfy the following expression with regard to the indices n2 and n4 introduced from the above relational expressions. That is, it is necessary to use a material having a refractive index between the refractive indices n2 and n4. If the refractive index is denoted by n6,
n2≦n6≦n4 or n4≦n6≦n2 (Expression 14).

Furthermore, it is preferable for the refractive index n6 to take the average value of the refractive indices n2 and n4 as the average value is expressed by the following expression.
n6=(n2+n4)/2 (Expression 15)

Moreover, if the film thicknesses of the first anti-reflection film 202 and the second anti-reflection film 204 that have the same refractive index n6 are made to be formed to have the same film thickness d6, the conditions of their manufacturing processes can be unified, and the their manufacturing costs can be further cut down. For example, it is also possible to manufacture both of the wafer to which the processes of the first anti-reflection film 202 are performed and the wafer to which the processes of the second anti-reflection film 204 are performed at the same time.

In the case of using the anti-reflection films made of the materials having the same refractive index n6 and being formed to have the same film thickness d6 as described above, it is needed to satisfy the following expression:
n2d2≦n6d6≦n4d4 or n4d4≦n6d6≦n2d2 (Expression 16).

Moreover, in order to more reduce the reflection, it is needed to satisfy the following expression:
n6d6=(n2d2+n4d4)/2 (Expression 17).

FIG. 9 is a graph pertaining to the image pickup apparatus provided with a first anti-reflection film and a second anti-reflection film, both of which have a refractive index 1.73. FIG. 9 illustrates the R/G ratios of the signals output from an image pickup apparatus including a CF to the total film thicknesses of the interlayer insulation films of the image pickup apparatus similarly to FIG. 8. It is known that R/G ratios do not change even if the total film thicknesses of the interlayer insulation films change in comparison with FIG. 8, and that color unevenness is reduced.

As described above, in the image pickup apparatus of the present exemplary embodiment, the color unevenness caused by the interference of reflected lights can be reduced. In particular, it becomes possible to reduce the color unevenness in the lighting having bright lines, and to obtain an image having good color rendering properties.

### Second Exemplary Embodiment

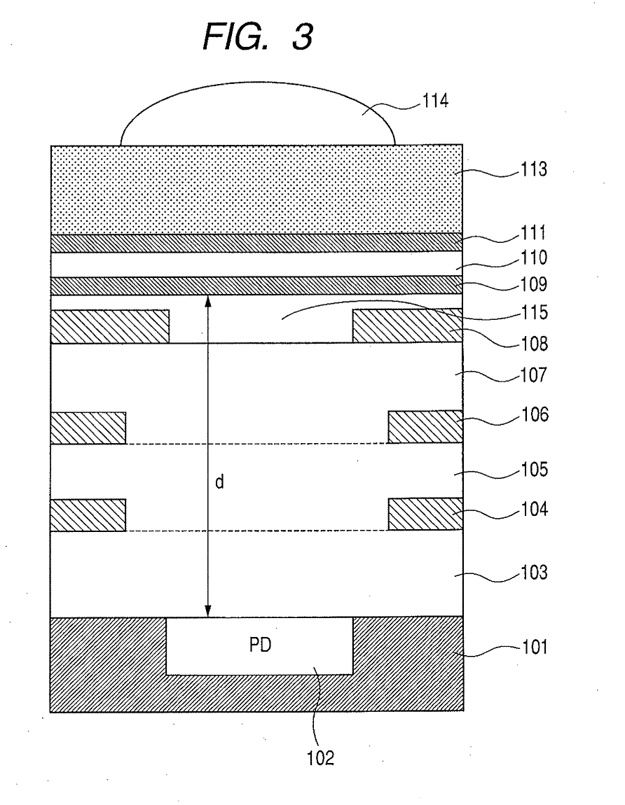

FIG. 3 illustrates a second exemplary embodiment. FIG. 3 is a schematic sectional view similar to FIG. 1. The components having the functions similar to those of FIG. 1 are denoted by the same reference marks as those of FIG. 1, and their descriptions are omitted.

The configuration of FIG. 3 includes a first insulation layer 115 on the third interlayer insulation film. Over the first insulation layer 115, the first anti-reflection film 109, the passiation layer 110, the second anti-reflection film 111 are disposed. Furthermore, over the second anti-reflection layer, the color filter 113 and the micro lens 114 are disposed. Hereupon, the first insulation layer may be an interlayer insulation film disposed at the uppermost part of the multi-layer wiring structure similarly to in the first exemplary embodiment.

In the present exemplary embodiment, the second insulation layer is the color filter 113. The color filter 113 in the present exemplary embodiment is made of the resin that has the refractive index of 1.58 similar to the resin layer 205 for planarization in the first exemplary embodiment. The functions of the anti-reflection films are similar to those of the first exemplary embodiment, and the designing of the anti-reflection films may be performed in consideration of the refractive index of the color filter 113.

According to the image pickup apparatus of the present exemplary embodiment, the color filter 113 can be formed on the second anti-reflection film 111, and the thinning of the image pickup apparatus can be performed consequently. In consequence, the incidence efficiency of the light receiving unit can be improved by lessening the aspect ratio from the micro lens 114 to the light receiving unit. Consequently, it becomes possible to provide the image pickup apparatus that improves the incidence efficiency, reducing color unevenness.

(Application to Digital Camera)

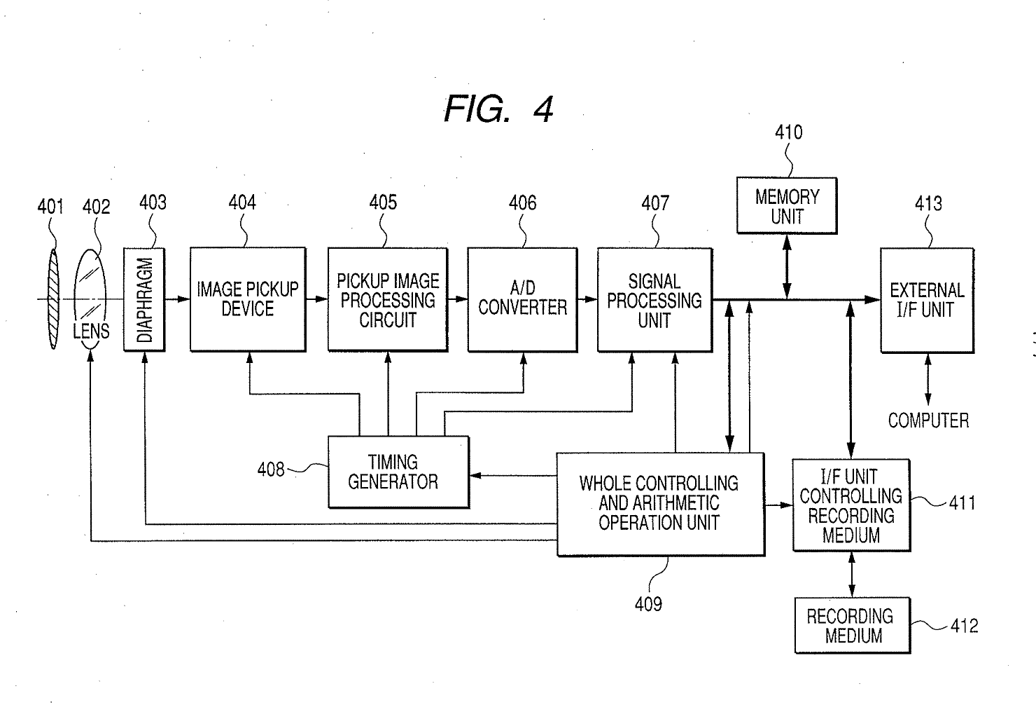

As an example of using the image pickup apparatus described pertaining to the aforesaid exemplary embodiments to an image pickup system, a block diagram in the case of the application of the pickup apparatus to a digital camera is illustrated in FIG. 4.

As a configuration for taking in a light into an image pickup device 404, which is an image pickup apparatus, a shutter 401, an image pickup lens 402 and a diaphragm 403 are provided. The shutter 401 controls the exposure to the image pickup device 404, and an entered light is formed as an image on the image pickup device 404 by the image pickup lens 402. At this time, the light quantity of the light is controlled by the diaphragm 403.

A signal output from the image pickup device 404 according to the taken-in light is processed by a pickup image processing circuit 405, and is converted from an analog signal to a digital signal by an A/D converter 406. The output digital signal further receives arithmetic processing by a signal processing unit 407, and pickup image data is generated. The pickup image data can be stored into a memory unit 410 mounted in the digital camera, or can be transmitted to external equipment such as a computer or a printer through an external I/F unit 413 according to the setting of an operational mode by a photographer. Moreover, it is also possible to record the pickup image data on a recording medium 412, which is detachably attachable to the digital camera, through an I/F unit controlling recording medium 411.

The image pickup device 404, the pickup image processing circuit 405, the A/D converter 406 and the signal processing unit 407 are controlled by a timing generator 408, and the whole system is controlled by a whole controlling and arithmetic operation unit 409. Moreover, the whole system can be also formed on the same semiconductor substrate (FIG. 1) of the image pickup device 404 by the same processing.

The digital camera in which color unevenness is reduced can be provided by the configuration as mentioned above.

(Application to Video Camera)

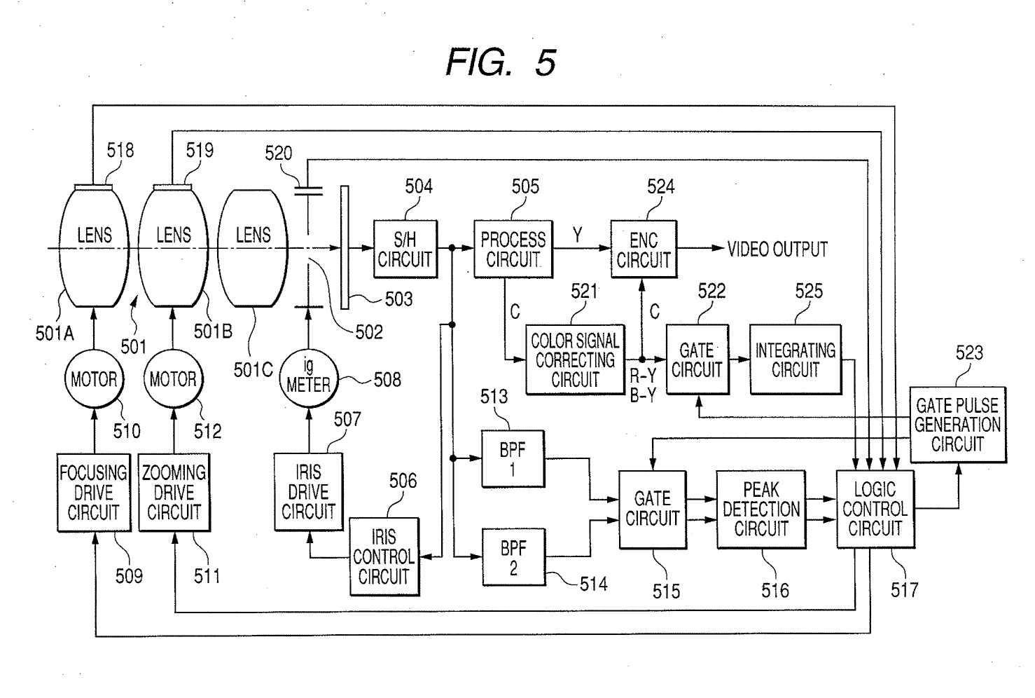

FIG. 5 is a block diagram illustrating the case where the image pickup apparatus described pertaining to the above exemplary embodiments are applied to a video camera, which is another example of the image pickup system. In the following, the video camera is described in detail based on FIG. 5.

A taking lens 501 includes a focus lens 501A for performing focusing, a zoom lens 501B performing a zoom operation, and an image formation lens 501C. The video camera includes a diaphragm and shutter 502 and an image pickup apparatus 503 performing the photoelectric conversion of a subject image formed on an image pickup surface to convert the subject image to an electric pickup image signal. A sample hold circuit (S/H circuit) 504 performs the sample hold of the pickup image signal output from an image pickup apparatus 503 and the amplification of the level of the pickup image signal, and the sample hold circuit 504 outputs an image signal.

A process circuit 505 performs the predetermined processing such as gamma correction, color separation and blanking processing to the image signal output from the sample hold circuit 504, and outputs a luminance signal Y and a chroma signal. The chroma signal output from the process circuit 505 receives the corrections of white balance and color balance by a color signal correction circuit 521, and is output from the color signal correction circuit 521 as chrominance difference signals R-Y and B-Y.

Moreover, the luminance signal Y output from the process circuit 505 and the chrominance difference signals R-Y and B-Y output from the color signal correction circuit 521 are modulated by an encoder circuit (ENC circuit) 524, and are output from the ENC circuit 524 as a standard television signal. Then, the standard television signal is supplied to a not shown video recorder, or an electric view finder such as a monitor electric view finder (EVF).

Next, the video camera includes an iris control circuit 506. The iris control circuit 506 controls an iris drive circuit 507 based on an image signal supplied from the sample hold circuit 504, and automatically controls an ig meter 508 in order to control the opening quantity of the diaphragm 502 so that the level of the image signal may be a constant value of a predetermined level.

Band-pass filters (BPF) 513 and 514 extract high-frequency components necessary for performing in-focus detection among the image signals output from the sample hold circuit 504. The signals output from the first band-pass filter 513 (BPF 1) and second band-pass filter 514 (BPF 2), which severally restrict a band different from each other, are severally gated by a gate circuit 515 and a focus gate frame signal. Then, the peak values of the gated signals are detected by a peak detection circuit 516, and the detected peak values are held by the peak detection circuit 516. The peak values are also input into a logic control circuit 517. The peak values are called as focus voltages, and the focus of the taking lens 501 is adjusted by the focus voltages.

Moreover, a focus encoder 518 detects a moved position of the focus lens 501A. A zoom encoder 519 detects the in-focus of the zoom lens 501B. An iris encoder 520 detects the opening quantity of the diaphragm 502. The detected values of the encoders are supplied to the logic control circuit 517 performing system control.

The logic control circuit 517 performs the in-focus detection to a subject based on the image signal corresponding to a set in-focus detection area to perform focusing. That is, the logic control circuit 517 takes therein the peak value information of the high-frequency component supplied from each of the band-pass filter 513 and 514, and drives the focus lens 501A to the position at which the peak value of the high-frequency component becomes the maximum. For that sake, the logic control circuit 517 supplies control signals of the rotation direction, the rotation speed, the rotation/stopping of a focus motor 510 to a focusing drive circuit 509, and controls the focusing drive circuit 509.

A zooming drive circuit 511 rotates a zoom motor 512 when zooming is instructed. When the zoom motor 512 rotates, the zoom lens 501B moves, and zooming is performed.

As described above, according to the image pickup apparatus of the present invention, the reduction of the reflection at the interfaces of a passiation layer becomes possible in the phenomenon in which the light reflected on the surface of the light receiving unit is reflected at the interfaces of the passiation layer and enters the light receiving unit again. Moreover, also as for the reflection at the interface of each of the anti-reflection films, it becomes possible to reduce the quantities of the reflected lights by making the reflected lights interfere with each other by adopting the film thicknesses of the anti-reflection films according to the present invention. In consequence, it becomes possible to reduce color unevenness to obtain image information having high quality.

The modes of the present invention are not limited to each exemplary embodiment. For example, each anti-reflection film may have a multilayer structure, and also the film type thereof is not limited to the exemplified ones. In any case, it is just needed for each anti-reflection film to have the effect of reducing reflections. Moreover, the structures above and below the anti-reflection films are not limited especially. It is just needed to consider the relations between the layers that the anti-reflection films contact with and the anti-reflection films. Besides, for example, each wiring layer may be two layers, and the materials and processes of the insulation layers and the wiring layers are not limited to those shown in each exemplary embodiment.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2006-059589, filed Mar. 6, 2006, which is hereby incorporated by reference herein in its entirety.

What is claimed is:

1. An image pickup apparatus comprising:
a plurality of photoelectric conversion elements disposed on a semiconductor substrate;
a multi-layer wiring structure including a plurality of interlayer insulation films disposed over the semiconductor substrate;
a passivation layer disposed over the multi-layer wiring structure;
a first insulation layer disposed below the passivation layer and having a refractive index differed from the refractive index of the passivation layer; and
a second insulation layer disposed above the passivation layer and having a refractive index differed from the refractive index of the passivation layer, wherein
planarization processing is performed to at least one layer of the plurality of interlayer insulation films or the first insulation layer;
a first anti-reflection film is disposed between the passivation layer and the first insulation layer;
a second anti-reflection film is disposed between the passivation layer and the second insulation layer; and
the first insulation layer, the first anti-reflection film, the passivation layer, the second anti-reflection film, the second insulation layer are laminated in this turn.

2. The image pickup apparatus according to claim 1, wherein the first insulation layer constitutes a part of the multi-layer wiring structure.

3. The image pickup apparatus according to claim 1, wherein
the refractive indices of the first anti-reflection film and the second anti-reflection film are equal to each other, and
film thicknesses of the first anti-reflection film and the second anti-reflection film are equal to each other.

4. The image pickup apparatus according to claim 1, wherein at least one of the first anti-reflection film and the second anti-reflection film includes a plurality of films.

5. The image pickup apparatus according to claim 1, wherein
the passivation layer has the refractive index higher than those of the first insulation layer and the second insulation layer; and
when a film thickness and the refractive index of the first anti-reflection film are denoted by d1 and n1, respectively, and when the film thickness and the refractive index of the second anti-reflection film are denoted by d2 and n2, respectively, and further when an average wavelength of bright lines of green and red of a three band fluorescent light is denoted by λ1, the film thicknesses and refractive indices of the first and the second anti-reflection films are within the following ranges:
λ1/4≦2n1d1≦3λ1/4, and
λ1/4≦2n2d2≦3λ1/4.

6. The image pickup apparatus according to claim 1, wherein, at light receiving units of the photoelectric conversion elements, variation of thicknesses from tops of the light receiving units of the photoelectric conversion elements to a top surface of the first insulation layer is one sixth of a wavelength of an incident light or more.

7. The image pickup apparatus according to claim 1, wherein the planarization processing is performed by a CMP method.

8. An image pickup apparatus comprising:
a photoelectric conversion element disposed on a semiconductor substrate;
a multi-layer wiring structure disposed on the semiconductor substrate, the multi-layer wiring structure including an interlayer insulation film;
a silicon nitride film disposed above the multi-layer wiring structure;
a first insulation layer disposed below the silicon nitride film and having a refractive index differed from the refractive index of the passivation layer; and
a second insulation layer disposed above the silicon nitride film and having a refractive index differed from the refractive index of the passivation layer, wherein
at least one layer of the interlayer insulation film or the first insulation layer has a surface processed by a CMP method,
a first silicon oxide nitride film is disposed between the silicon nitride film and the first insulation layer, and
a second silicon oxide nitride film is disposed between the silicon nitride film and the second insulation layer, wherein
the first insulation layer, the first silicon oxide nitride film, the passivation layer, the second silicon oxide nitride film, the second insulation layer are laminated in this turn.

9. The image pickup apparatus according to claim 8, wherein thicknesses of the first silicon oxide nitride film and the second silicon oxide nitride film are equal to each other.

10. An image pickup system comprising:
the image pickup apparatus according to claim 1;
an optical system performing image formation of light onto the image pickup apparatus; and
a signal processing circuit processing an output signal from the image pickup apparatus.
